(19) United States
(12) Patent Application Publication
(10) Pub. No.: US 2003/0181056 A1
(43) Pub. Date: Sep. 25, 2003

(54) Method of etching a magnetic material film stack using a hard mask

(75) Inventors: Ajay Kumar, Sunnyvale, CA (US); Padmapani C. Nallan, San Jose, CA (US)

Correspondence Address: Patent Counsel, Applied Materials, Inc., P. O. Box 450A, Santa Clara, CA, 95052, US

(73) Assignee: Applied Materials, Inc.

(21) Appl. No.: 10/218,271

(22) Filed: Aug. 12, 2002

Related U.S. Application Data
(60) Provisional application No. 60/366,746, filed on Mar. 22, 2002.

(51) Int. Cl. H01L 21/302; H01L 21/461

(52) U.S. Cl. 438/710

(57) ABSTRACT

A method of etching a film stack that includes at least one layer of magnetic material comprises forming a high temperature mask on the film stack. The film stack is then etched. During the etching process, a residue is formed that comprises components of the high temperature mask. Since the residue and the high temperature mask comprise primarily the same material, the high temperature mask and the residue are simultaneously removed. The method may be used to form a film stack for use in a magneto-resistive random access memory (MRAM) device.

### BACKGROUND OF THE INVENTION

This invention claims the benefit of U.S. provisional patent application serial No. 60/366,746 filed Mar. 22, 2002, which is herein incorporated by reference in its entirety.

### FIELD OF THE INVENTION

Embodiments of the present invention generally relate to a method of etching film stacks. More specifically, the invention relates to a method of etching a film stack that includes a magnetic material using a hard mask.

### DESCRIPTION OF THE RELATED ART

Microelectronic devices are generally fabricated on a semiconductor substrate as integrated circuits. An example of such a device is a magneto-resistive random access memory (MRAM) device. An MRAM typically comprises multi-layer films or “film stacks” containing magnetic materials that may be patterned and etched to form information storage elements.

During a plasma etching process of a magnetic material film stack, various layers within the film stack are etched using a plasma that may comprise, for example, fluorine or chlorine species. The chlorine or fluorine species may combine with material removed from, for example, a conductive layer and a photoresist layer in the film stack to form a conductive residue that deposits along the sidewalls of the film stack. This conductive residue becomes tenacious as various layers of the film stack are subjected to a high temperature etch process that is typically used to etch the magnetic material layers in the film stack. Furthermore, the conductive residue may redeposit on portions of the film stack such that an electrical short circuit is created, thereby rendering devices made from the film stack inoperable.

Therefore, there is a need in the art for an improved method for etching a film stack that comprises a magnetic material.

### SUMMARY OF THE INVENTION

The disadvantages of the prior art are overcome by a method of etching a multi-layer film stack that comprises a magnetic material. The method comprises forming a high temperature mask on the film stack. The film stack is then etched. During the etching process, a residue is formed that comprises components of the high temperature mask. Since the residue and the high temperature mask comprise primarily the same material, the high temperature mask and the residue are simultaneously removed.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic diagram of one embodiment of a plasma processing apparatus that may be used to practice embodiments of the invention described herein;

FIGS. 2A-2G are cross-sectional views of a substrate during different stages an integrated circuit processing sequence consistent with one example of an embodiment of the invention described herein;

FIGS. 3A-3D are cross-sectional views of a substrate during different stages an integrated circuit processing sequence consistent with one example of an alternative embodiment of the invention described herein;

FIG. 4 depicts a schematic, cross-sectional view of one embodiment of a wet cleaning module that may be used to practice embodiments of the invention; and

FIG. 5 depicts a schematic view of one embodiment of an integrated platform that may be used to practice embodiments of the invention.

### DETAILED DESCRIPTION

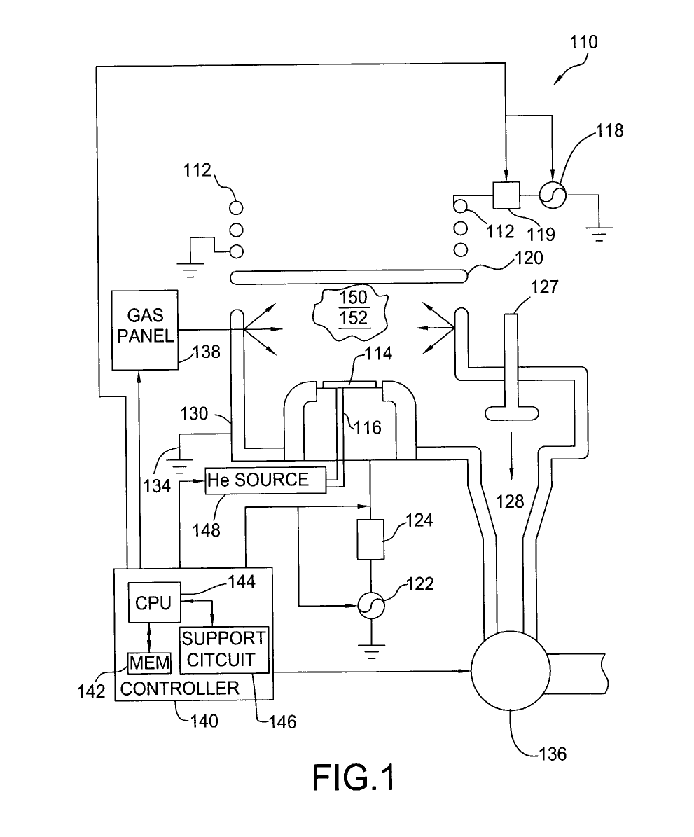

The present invention generally provides a method of etching a film stack that includes at least one layer of magnetic material. FIG. 1 depicts a schematic diagram of an etch chamber 110 that may be used to practice embodiments of the invention described herein. The etch chamber 110 may be, for example, a DPS II etch module of the Centura® metal etch system, commercially available from Applied Materials, Inc. of Santa Clara, Calif. The etch chamber 110 comprises at least one inductive coil antenna 112, positioned exterior to a dielectric, and a ceiling 120. The ceiling 120 may be flat, as shown in FIG. 1, or alternatively, the ceiling 120 may have another shape, such as a dome shape. The antenna 112 is coupled to a radio-frequency (RF) source 118 that is generally capable of producing an RF signal having a tunable frequency of about 2 MHz. The RF source 118 is coupled to the antenna 112 through a matching network 119. The etch chamber 110 also includes a substrate support pedestal (cathode) 116 that is coupled to a second RF source 122 that is generally capable of producing an RF signal having a frequency of approximately 13.56 MHz. The source 122 is coupled to the cathode 116 through a matching network 124. The etch chamber 110 also contains a conductive chamber wall 130 that is connected to an electrical ground 134. A controller 140 comprising a central processing unit (CPU) 144, a memory 142, and support circuits 146 for the CPU 144 is coupled to the various components of the etch chamber 110 to facilitate control of the etch process.

In operation, a substrate 114 is placed on the substrate support pedestal 116 and gaseous components are supplied from a gas panel 138 to the etch chamber 110 through entry ports 126 to form a gaseous mixture 150. The gaseous mixture 150 is ignited into a plasma 152 in the etch chamber 110 by applying RF power from the RF sources 118 and 122 to the antenna 112 and the cathode 116 respectively. The pressure within the interior of the etch chamber 110 is controlled using a throttle valve 127 situated between the etch chamber 110 and a vacuum pump 136. The temperature at the surface of the chamber walls 130 is controlled using liquid-containing conduits (not shown) that are located in the walls 130 of the chamber 110.

The temperature of the substrate 114 is controlled by stabilizing the temperature of the support pedestal 116 and flowing helium gas from a source 148 to channels formed by the back of the substrate 114 and grooves (not shown) on the pedestal surface. The helium gas is used to facilitate heat transfer between the pedestal 116 and the substrate 114. During the etch process, the substrate 114 is heated by a resistive heater within the pedestal to a steady state temperature and the helium facilitates uniform heating of the substrate 114. Using thermal control of both the ceiling 120 and the pedestal 116, the substrate 114 may be maintained at a temperature of between about 0 and about 500 degrees Celsius.

The RF power applied to the inductive coil antenna 112 has a frequency between 50 kHz and 13.56 MHz and has a power of 200 to 3000 Watts. The bias power applied to the pedestal 116 may be DC or RF and is between about 0 and about 100 Watts.

Those skilled in the art will understand that other forms of etch chambers may be used to practice the invention, including chambers with remote plasma sources, microwave plasma chambers, electron cyclotron resonance (ECR) plasma chambers, and the like.

To facilitate control of the chamber as described above, the CPU 144 may be one of any form of general purpose computer processor that can be used in an industrial setting for controlling various chambers and sub-processors. The memory 142 is coupled to the CPU 144. The memory 142, or computer-readable medium, may be one or more of readily available memory such as random access memory (RAM), read only memory (ROM), floppy disk, hard disk, or any other form of digital storage, local or remote. The support circuits 146 are coupled to the CPU 144 for supporting the processor in a conventional manner. These circuits include cache, power supplies, clock circuits, input/output circuitry and subsystems, and the like. An etching process is generally stored in the memory 142 as a software routine. The software routine may also be stored and/or executed by a second CPU (not shown) that is remotely located from the hardware being controlled by the CPU 144.

The software routine is executed after a wafer 114 is positioned on the pedestal 116. The software routine when executed by the CPU 144, transforms the general purpose computer into a specific purpose computer (controller) 140 that controls the chamber operation such that the etching process is performed. Although the process of the present invention is discussed as being implemented as a software routine, some of the method steps that are disclosed therein may be performed in hardware as well as by the software controller. As such, the invention may be implemented in software as executed upon a computer system, in hardware as an application specific integrated circuit or other type of hardware implementation, or a combination of software and hardware.

Method of Etching a Film Stack

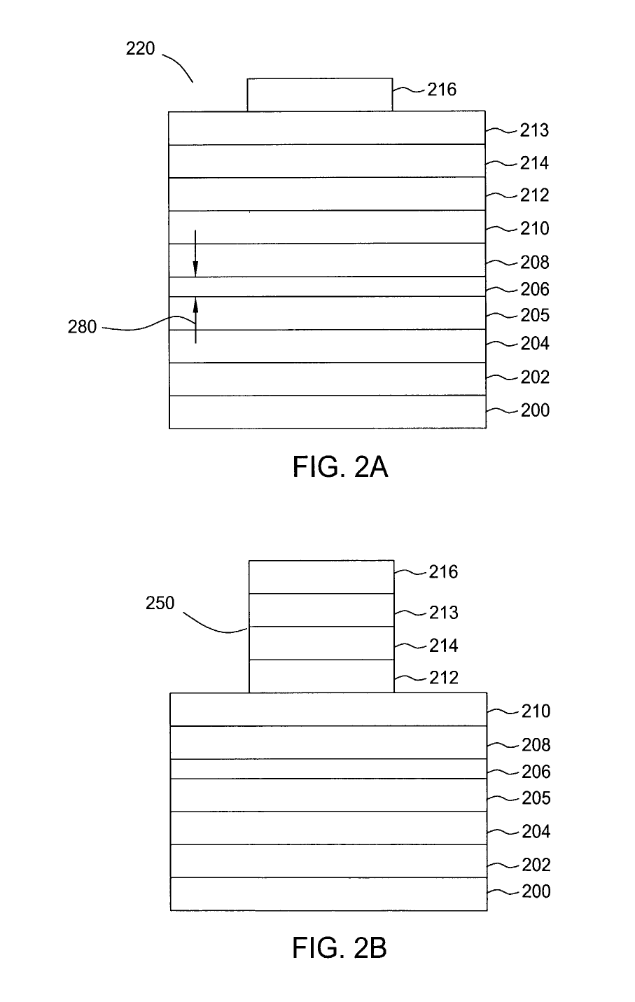

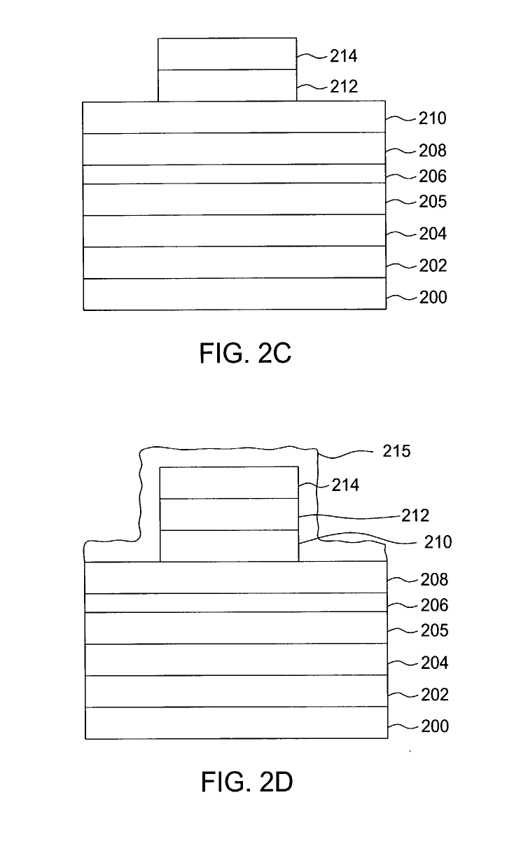

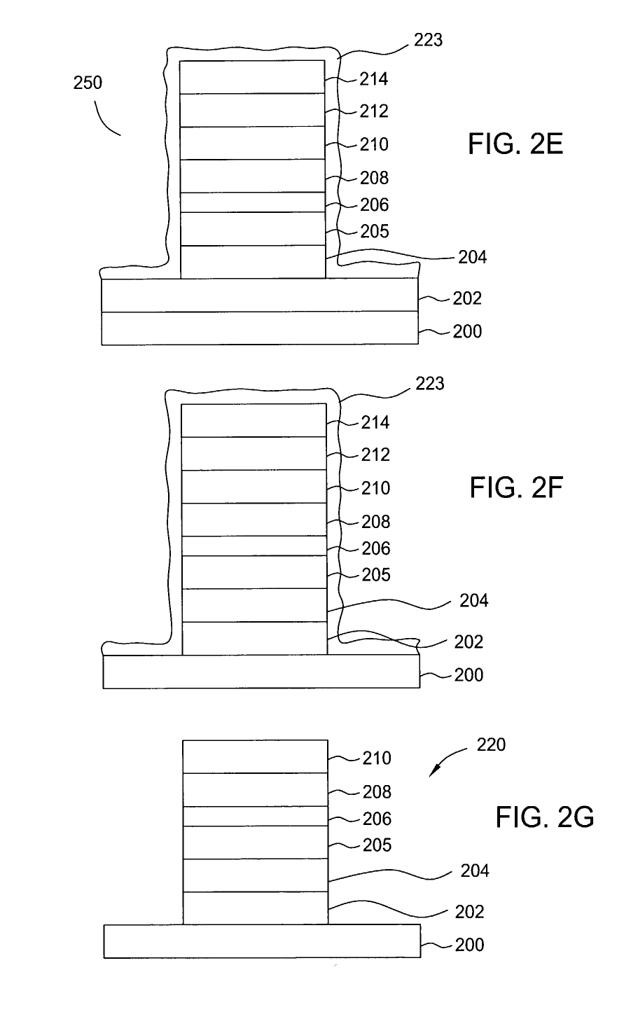

FIGS. 2A-2G are cross-sectional views of a film stack 220 during different stages of an integrated circuit fabrication sequence. As shown in FIG. 2A, a multilayer film stack 220 is formed on the substrate 200. The film stack 220 comprises a series of material layers (not drawn to scale in FIGS. 2A-2G) formed in succession: a first conductive layer 202, a pinning layer 204, a first magnetic layer 205, a tunnel barrier or tunneling layer 206, a second magnetic layer 208, a second conductive layer 210 and a hard mask layer 212, a cap layer 214, a bottom antireflective coating (BARC layer) 213, and a patterned photoresist layer 216. Depending upon the particular stage of processing, the film stack 220 includes one or more of the material layers described above. The material layers of the film stack 220 may be in a patterned or unpatterned state depending on the stage of processing.

The first magnetic layer 205, the tunneling layer 206, and the second magnetic layer 208 collectively represent a magneto-resistive sensing element or magnetic tunnel junction (MTJ). The film stack 220 is, for example, used to magnetically encode or store information.

The first conductive layer 202 and the second conductive layer 210 generally function as electrodes and may comprise, for example, tantalum (Ta). Alternatively, one or both of the first conductive layer 202 and the second conductive layer 210 may comprise a sub-layer of tantalum nitride (TaN) that is used as a barrier layer to a patterned copper electrode. Each of the first conductive layer 202 and the second conductive layer 210 may have a thickness of about 300 to about 600 Angstroms. The first magnetic layer 205 and the second magnetic layer 208 comprise ferromagnetic materials such as nickel and cobalt iron alloys, such as CoFe, NiFe and the like, and may comprise one or more sub-layers of combinations of these alloys. The first magnetic layer 205 generally has a thickness of about of about 300-400 Angstroms and the second magnetic layer 208 generally has a thickness of about 50-100 Angstroms. The pinning layer 204 may comprise an anti-ferromagnetic material. The pinning layer 204 may comprise, for example, an alloy of platinum (Pt) and manganese (Mn), and generally functions to maintain a magnetic state of the second magnetic layer 208 in a specific direction.

The tunneling layer 206 may be a non-magnetic, electrically insulating layer of material, comprising, for example, alumina (Al₂O₃) and may have a thickness, of about 10 Angstroms to about 15 Angstroms. Under certain conditions (e.g. upon receiving an input signal having a current or voltage within a particular range), a tunneling current flows across a thickness 280 of the tunneling layer 206. The amount of this current is controlled by the magnetic states of the magnetic layers 205 and 208.

The hard mask layer 212 is a high temperature mask layer that may comprise an inorganic carbon material such as amorphous carbon. In one embodiment of the invention, the hard mask layer 212 comprises an inorganic carbon material doped with nitrogen. The nitrogen doping generally improves the etch selectivity of the hard mask layer 212 versus other materials within the film stack 220. The hard mask layer 212 may be deposited using conventional techniques, such as plasma enhanced chemical vapor deposition (CVD) or sputtering. The hard mask layer 212 is deposited to a thickness in a range of about 200 Angstroms to about 5000 Angstroms.

The cap layer 214 generally comprises a material that is resistant to the etching process used to etch various material layers in the film stack 220 (e.g. resistant to fluorine-based or chlorine-based etch gases). The cap layer 214 may comprise an oxide, a nitride, or an oxynitride material. The cap layer 214 may be deposited using conventional methods, such as PECVD and may be formed to a thickness in a range of about 100 to about 500 Angstroms.

The bottom antireflective coating (BARC) layer 213 is positioned between the photoresist layer 214 and the hard mask layer 212 in order to control reflections from the underlying second conductive layer 210 and thereby reduce the tendency of inaccuracies from developing when the pattern is transferred from the photoresist layer 214. The BARC layer 213 may comprise, for example, inorganic materials such as silicon nitride, silicon oxynitride, titanium nitride, silicon carbide, and the like, or organic materials such as polyamides and polysulfones. The BARC layer 213 and the patterned photoresist layer 216 together have a thickness of about 6000 Angstroms. The patterned photoresist layer 216 may be a conventional organic photosensitive layer used for the patterning of integrated circuits. The photoresist layer 216 is typically formed by applying photoresist to the substrate 200, exposing the photoresist through a mask, and developing the photoresist to form the photoresist layer 216. The regions of the hard mask layer 212, the BARC layer 213 and the cap layer 214 that are not protected by the photoresist layer 216 are etched, as indicated in FIG. 2B.

The etching of the hard mask layer 212, the BARC layer 213, and the cap layer 214 may be performed using, for example, an oxygen-based plasma and may be performed in an etch chamber similar to the etch chamber 110 of FIG. 1. The etching of the hard mask layer 212, the BARC layer 213, and the cap layer 214 may comprise supplying between 100 and 200 sccm of Argon, between 10 and 20 sccm of oxygen, applying power to an inductively coupled antenna between 300 and 1000 Watts, applying a cathode electrode bias power between 0 and 300 Watts, and maintaining a substrate temperature between 0 and 80 degrees Celsius as well as a pressure in the reactor between 2 and 30 mTorr. One specific process recipe provides 10 sccm of O₂, 100 sccm of Ar, applying 500 Watts to the antenna and 50 Watts to the cathode electrode, and maintaining a substrate temperature at 50 degrees Celsius and a pressure in the reactor at 4 mTorr.

The photoresist layer 216 as well as the BARC layer 213 are stripped, as shown in FIG. 2C. This stripping process may be performed, for example, in the Advanced Strip and Passivation (ASP) module of the Centura® system. The ASP module is a microwave downstream oxygen plasma reactor in which the plasma is confined to a plasma tube and only reactive neutrals are allowed to enter a process chamber. Such a plasma confinement scheme precludes plasma-related damage of the substrate 200 or circuits formed on the substrate. In the ASP module, backside of the substrate 200 is heated radiantly by quartz halogen lamps and the wafer temperature can be maintained between 20 to 400 degrees Celsius. A duration of a stripping process is generally between 20 and 100 seconds.

In one embodiment of the invention, the layers 216 and 213 are removed in the APS module by supplying between 500 and 3500 sccm of O₂, between 0 and 500 sccm of N₂, applying between 200 to 3000 Watts to excite a plasma, applying a cathode electrode bias power between 0 to 100 Watts, and maintaining a wafer temperature between 200 to 400 degrees Celsius and a pressure in the reactor between 1 to 10 Torr. In this embodiment of the invention, good results were observed with the oxygen-based reactant gas. One specific process recipe provides 3500 sccm of O₂, 500 sccm of N₂, applies 1400 Watts to excite a plasma, and maintains a wafer temperature at 200 degrees Celsius and a pressure in the reactor at 2 Torr.

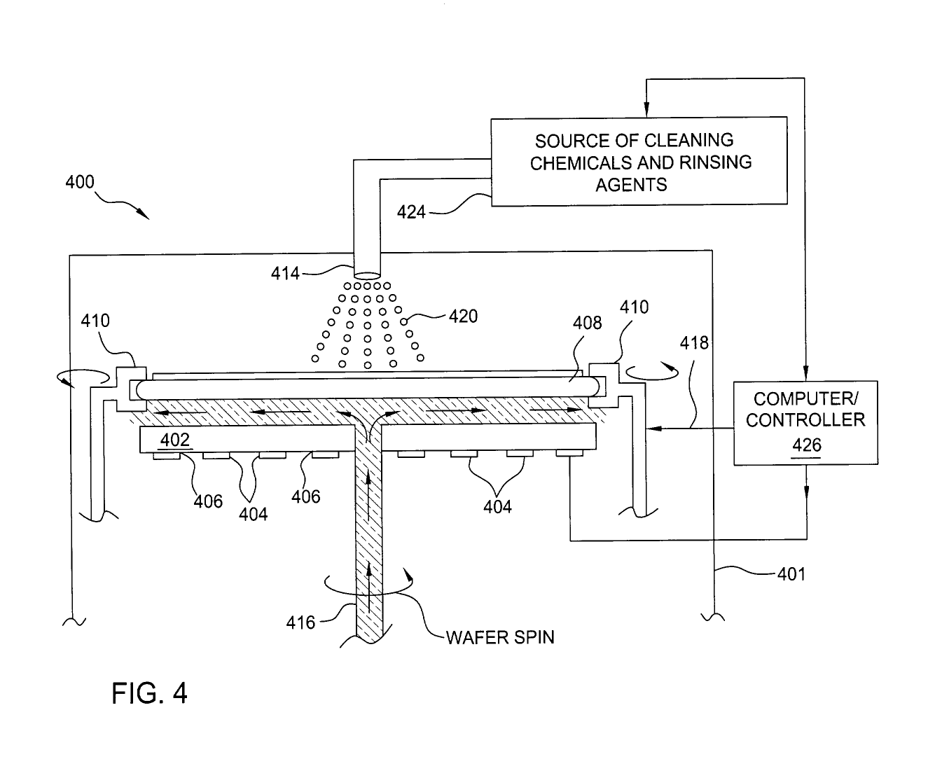

Alternatively, removal of the layers 216 and 213 may be performed in the DPS II module such as the etch chamber 110 of FIG. 1. In one embodiment of the invention, in the DPS II chamber, the layers 213 and 216 are removed by supplying between 20 and 200 sccm of O₂, between 10 and 100 sccm of N₂, applying power to an inductively coupled antenna about 1000 Watts, applying a cathode electrode bias power about 10 Watts, and maintaining a wafer temperature about 40 degrees Celsius and a pressure in the reactor about 32 mTorr for a duration of about 120 seconds. In this embodiment of the invention, a duration of the stripping process is between 10 and 100 seconds. After the stripping procedure, the substrate 200 may be wet dipped in a solvent such as EKC 265 to remove traces of the oxidized photoresist layer 216. EKC 265 is commercially available from EKC Technology, Inc., of Danville, Calif. Such a wet dip process may be performed using a single substrate wet cleaning module described below with reference to FIG. 4.

As shown in FIG. 2D, second conductive layer 210 is then etched. The hard mask layer 212 and the cap layer 214 protect portions of the material layers in the film stack 220. The second conductive layer 210 is plasma etched using either a chlorine-based or fluorine-based chemistry (e.g., CF₄/CHF₃/Ar and the like). In one embodiment of the invention, the second magnetic layer 208 is used as an etch stop layer. Alternatively, etching may be terminated upon a certain optical emission occurring (e.g., at wavelength of about 3630 Angstroms), upon a particular duration occurring, or upon some other indicator determining that the second conductive layer 210 has been removed. During this etching step, some amount of the etched metal (e.g., tantalum) from the second conductive layer 210 may combine with components (for example, chlorine (Cl₂) or fluorine (F)) of the etchant and by-products of the etching process and form a residue 215. The residue 215 also comprises a substantial amount of material from the hard mask layer 212. The residue 215 contaminates the side walls 250 of the film stack 220. The residue 215 is generally not removed before the next process step.

The etching of the second conductive layer 210 may be performed in a Decoupled Plasma Source (DPS) II module of the Centura® system, such as the chamber 110 of FIG. 1. The DPS II module uses a 2 MHz inductive plasma source to generate and sustain high density plasma. A wafer is biased by a 13.56 MHz bias source. The decoupled nature of the plasma source allows independent control of ion energy and ion density. The DPS II module provides a wide process window over changes in source and bias power, pressure, and etch gas chemistry and uses an endpoint system to determine an end of the etch process.

The etching of the second conductive layer 210 may comprise supplying between 10 and 200 sccm of Argon, applying power to an inductively coupled antenna between 200 and 3000 Watts, applying a cathode electrode bias power between 0 and 300 Watts, and maintaining a substrate temperature between 100 and 500 degrees Celsius as well as a pressure in the reactor between 2 and 10 mTorr. One specific process recipe provides 60 sccm of CF₄, 60 sccm of Ar, applying 1000 Watts to the antenna and 50 Watts to the cathode electrode, and maintaining a substrate temperature at 250 degrees Celsius and a pressure in the reactor at 10 mTorr.

Referring to FIG. 2E, etching of the second magnetic layer 208, the tunneling layer 208, the first magnetic layer 205 and the pinning layer 204 is performed using for example, a boron chloride (BCl₃) chemistry (for example, Ar/BCl₃ and the like) as an etchant. The high temperature hard mask 212 is used as an etch mask and the first conductive layer 202 as an etch stop layer. A boron chloride (BCl₃) chemistry (for example, Ar/BCl₃ and the like) may be used as the etchant. The etching of the second magnetic layer 208, the tunneling layer 206, the first magnetic layer 205 and the pinning layer 204 may be performed in a DPS II module of the Centura® system by supplying between 10 and 200 sccm of BCl₃ and between 10 and 200 sccm of Ar, applying power to an inductively coupled antenna between 200 to 3000 Watts, applying a cathode electrode bias power between 0 to 300 Watts, and maintaining a wafer temperature between 20 to 250 degrees Celsius and a pressure in the reactor between 2 to 20 mtorr. One specific process recipe provides 20 sccm of BCl₃, 80 sccm of Ar, applying 700 Watts to the antenna and 150 Watts to the cathode electrode, and maintaining a wafer temperature at 80 degrees Celsius and a pressure in the reactor at 5 mtorr.

Some by-products of the etching process that have a low volatility may produce a metal-containing residue 223. The residue 223 may include components of the hard mask 214 as well as metallic components such as, for example, tantalum, tantalum nitride, titanium nitride, cobalt, iron, nickel, ruthenium, platinum, and combinations thereof. The residue 223 may include components of the residue 215. The residue 223 typically forms on the sidewalls 250 and on the top of the cap layer 214. The residue 223 is generally not removed before the next process step.

The first conductive layer 202 may be etched, as shown in FIG. 2F using a Cl₂ based etchant such as Cl₂/Ar and the like. In one embodiment of the invention, the first conductive layer 202 is etched using the hard mask 212 and the cap layer 214 as an etch mask and a barrier layer (not shown) that may be formed between the substrate 200 and the first conductive layer 202 as an etch stop layer. The etch process may be performed in a DPS II module of the Centura® system by supplying between 10 and 200 sccm of Cl₂ and between 10 and 500 sccm of Ar, applying power to an inductively coupled antenna between 200 to 3000 Watts, applying a cathode electrode bias power between 0 to 300 Watts, and maintaining a wafer temperature between 20 to 250 degrees Celsius and a pressure in the reactor between 2 to 20 mTorr. One specific process recipe provides 20 sccm of Cl₂, 200 sccm of Ar, applying 1500 Watts to the antenna, applying 300 Watts to the cathode electrode, and maintaining a wafer temperature at 250 degrees Celsius and a pressure in the reactor at 5 mTorr.

As indicated in FIG. 2G, the residue 223 that has accumulated during one or more of the etching processes is removed from the film stack 220. Since the residue 223 comprises a substantial amount of the mask material, e.g., amorphous carbon, the residue 223 is readily removable using an ashing process. Furthermore, the cap layer 214 and the hard mask layer 212 may also be removed. The removal of the residue 223, the cap layer 214, and the hard mask layer 212 may be performed by ashing in an oxygen-based plasma in a module such as the Advanced Strip and Passivation module (ASP) of the Centura® metal etch system, commercially available from Applied Materials Inc., of Santa Clara, Calif. In one embodiment of the invention, the residue 223, the cap layer 214, and the hard mask layer 212 are removed in a etch chamber such as the DPS II chamber by supplying between 10 and 200 sccm of O₂ and between 10 and 200 sccm of Ar, applying power to an inductively coupled antenna between 500 to 1500 Watts, applying a cathode electrode bias power between 50 to 500 Watts, and maintaining a wafer temperature between 20 to 250 degrees Celsius and a pressure in the reactor between 2 to 20 mtorr.

Following the removal of the residue 223, the cap layer 214 and the hard mask layer 212, the substrate 200 may be rinsed and cleaned with a solvent such as, for example, EKC 265 to remove traces of the cap layer 214, the hard mask layer 212, and the residue 223.

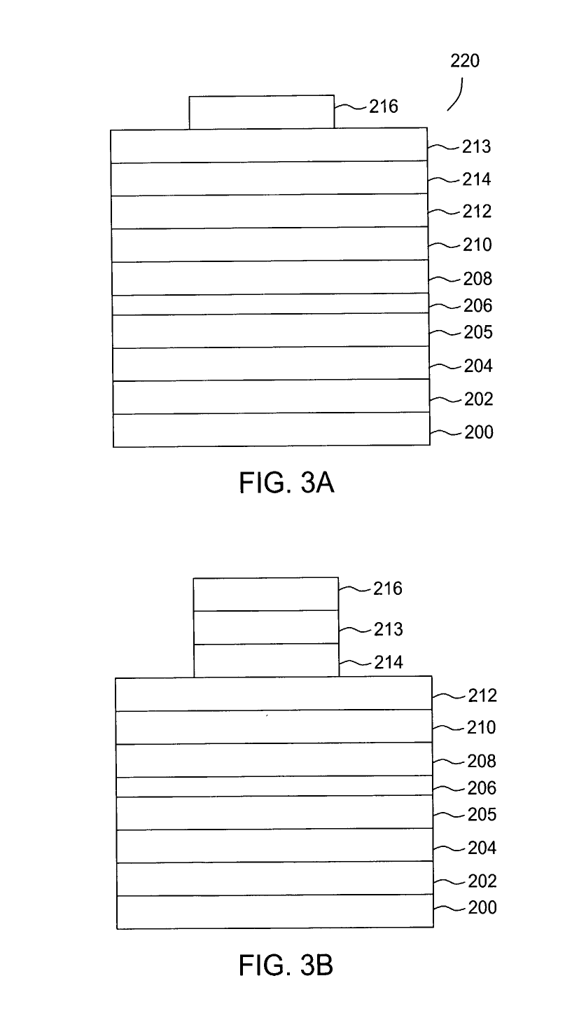

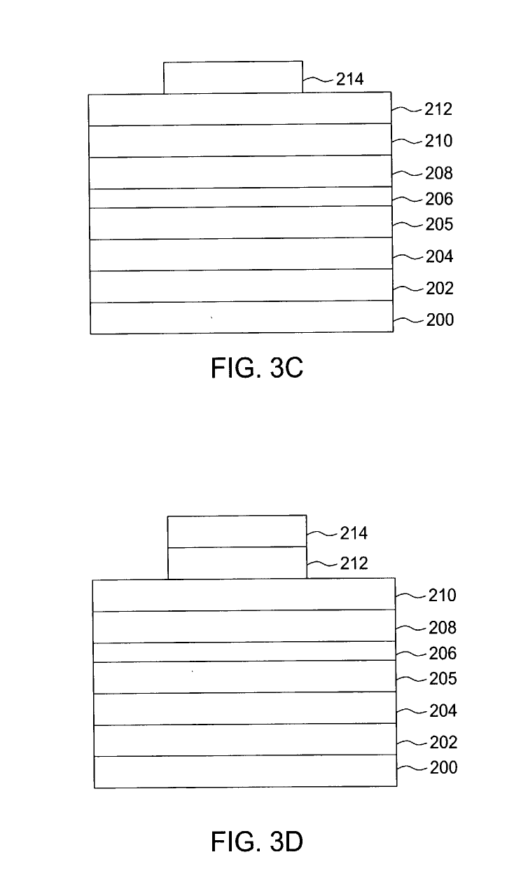

While FIGS. 2A-2G depict an etch process in which features formed in the photoresist layer 216 are used to etch the cap layer 214 and the hard mask layer 212, alternative process steps may be used where the photoresist layer 216 is used to only pattern the cap layer 214, and the cap layer 214 is then used to pattern the mask 212. For example, FIGS. 3A-3D depict cross-sectional views of the film stack 220 during different stages of an MRAM fabrication sequence according to an alternative embodiment of the invention.

Referring to FIG. 3A, the film stack 220 comprises the first conductive layer 202, the pinning layer 204, the first magnetic layer 205, the tunneling layer 206, the second magnetic layer 208, the second conductive layer 210, the hard mask layer 212, the cap layer 214, the BARC layer 213, and the patterned photoresist layer 216 formed successively on the substrate 200. As shown in FIG. 3B, the cap layer 214 is etched using the patterned photoresist layer 216 as a mask and stopping on the hard mask 212. The photoresist layer 216 is then stripped as shown in FIG. 3C using process conditions that may be similar to those discussed above with reference to FIG. 2C. The cap layer 214 is then used as a mask to etch the hard mask layer 212, as shown in FIG. 3D. The film stack 220 is then etched in a manner as described above and shown in FIGS. 2C-2G.

The method of the present invention of etching the film stack 220 comprising magnetic layers is simplified over the prior art. The high temperature mask (the hard mask layer 212) enables high temperature etching of the material layers, such as the conductive layers 202, 213, the magnetic layers 205, 208 and the tunneling layer 206 in the film stack. Furthermore, residue that may be generated during the etching of the film stack 229 contains a substantial amount of the material from the hard mask, e.g., amorphous carbon, and thus may be readily removed when the hard mask layer 212 is removed.

The method of the present invention periodically cleans the substrate by dipping the substrate into a cleaning solution (cleaning chemicals and/or rinsing agents such as EKC 265 and deionized water). One embodiment of an apparatus for cleaning a substrate is a single substrate wet cleaning module. FIG. 4 depicts a simplified cross-sectional view of an illustrative embodiment of a single substrate wet cleaning module 400. The module 400 is described in detail in U.S. patent application Ser. No. 09/945,454, filed Aug. 31, 2001 (attorney docket number 4936), which is herein incorporated by reference.

The module 400 applies cleaning chemicals and/or rinsing agents to the top and bottom of a substrate. To enhance the cleaning process, the module 400 uses acoustic or sonic waves to agitate the cleaning chemicals and/or rinsing agents.

The module 400 comprises a chamber 401, a nozzle 414, and a substrate support 412. The substrate support is mounted within the chamber 401 and comprises edge clamps 410, plate 402 and a plurality of acoustic or sonic transducers 404. The plate 402 has a shape that is substantially the same as a substrate and supports the plurality of acoustic or sonic transducers 404. The plate 402 is, for example, made of aluminum, but can be formed of other materials such as, but not limited to, stainless steel and sapphire. The plate 402 is coated with a corrosion resistant fluoropolymer such as HALAR or PFA. The transducers 404 are attached to the bottom of the plate 402 using an adhesive, for example, an epoxy 406. In one embodiment of the cleaning module 400, the transducers 404 are arranged in an array that covers substantially the entire bottom surface of plate 402, e.g., approximately 80% of plate 402. The transducers generate sonic waves in the frequency range between 400 kHz and 8 MHz. In one embodiment of the module 400, the transducers are piezoelectric devices.

The plurality of edge clamps 410 retain the substrate 408 face up above the plate 408 to form a gap 418 between the backside of the wafer and the top surface of the plate 402. The gap 418 is approximately 3 mm. Cleaning chemicals and/or rinsing agents are provides to the gap via channel 416. The clamps are rotated to cause the substrate 408 to rotate about its central axis at a rate between 0 and 6000 rpm. In this embodiment of module 400, the substrate 408 and clamps 410 rotate, while the plate 402 is stationary.

The nozzle 414 sprays cleaning chemicals and/or rinsing agents upon the top of the substrate 408 (i.e., the surface of the substrate comprising features, transistors, or other circuitry). As the nozzle 414 sprays the top of the substrate 408, the same or different cleaning chemicals and/or rinsing agents are supplied to the gap 418 via channel 416 as the substrate is rotated such that the cleaning chemicals and/or rinsing agents flow across the top and bottom surfaces of the substrate.

The nozzle 414 and channel 416 are coupled to a source 424 of cleaning chemicals and/or rinsing agents. The source 424 may be the same for the nozzle 414 and channel 416, or a separate source may be couple to each of the nozzle 414 and channel 416. In the present embodiment of the invention, the module 400 is used to clean the substrate 408 using EKC 265 and deionized water.

A computer controller 426 is generally used to control the operation of the module 400. Specifically, the computer controller 426 controls the rotation of the substrate support 412, the activation of the transducers 404, the supply of cleaning chemicals and/or rinsing agents, and so on.

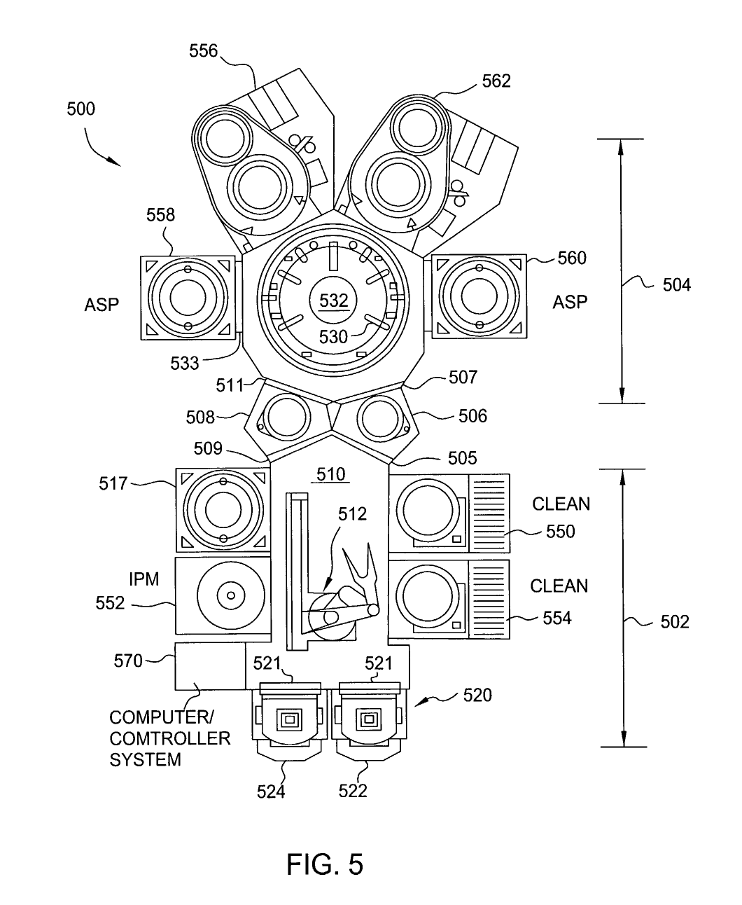

The method of the present invention is illustratively performed on an integrated processing platform 500 shown in FIG. 5 that comprises apparatus for performing both atmospheric and sub-atmospheric processing. The platform 500 and the various modules and tools that can be used with such a platform are described in detail in U.S. patent application Ser. No. 09/945,454, filed Aug. 31, 2001 (attorney docket number 4936), which is herein incorporated by reference.

Depending upon the process modules that are used in the platform 500, the platform 500 (also referred to as a process tool) can be used to perform etching, substrate cleaning, photoresist stripping, substrate inspection and the like. The platform 500 comprises an atmospheric platform 502 and a sub-atmospheric platform 504. The sub-atmospheric platform 504 and the atmospheric platform 502 may be coupled together by a single substrate load lock 506 or, as shown in the depicted example, are coupled together by a pair of single load locks 506 and 508. In some applications, the sub-atmospheric and atmospheric platforms 504 and 502 are not coupled together and may be used separately. One such stand-alone platform configuration may contain photoresist stripping modules and wet cleaning modules for providing a platform that performs post-etch processing.

The atmospheric platform 502 comprises a central atmospheric transfer chamber 510 containing a substrate handling device 512, such as a robot. Directly attached to the atmospheric transfer chamber 510 is a substrate wet cleaning module 550 (for example, module 400 of FIG. 4 could be used in this position), an integrated particle monitor 552 and a critical dimension (CD) measuring tool 554. A strip or dry clean module 517 can also be attached to the atmospheric transfer chamber 510, if desired. Each module or tool is coupled to the transfer chamber 510 by a separately closable and sealable opening, such as a slit valve. The transfer chamber is maintained at substantially atmospheric pressure during operation. The substrate handling device 512 is able to transfer substrates from one module or tool to another module or tool that is attached to the atmospheric transfer chamber 510. In the embodiment shown, the substrate handling device 512 is a dual blade, single arm, single wrist robot. Other types of robots may be used to access the various modules and tools.

The atmospheric transfer chamber 510 is coupled to at least one substrate input/output module 520 that provides and receives substrates to and from the platform 500. In one embodiment of the platform 500, the module 520 comprises at least one front opening unified pod (FOUP). Two FOUPs 522 and 524 are depicted. The substrate handling device 512 accesses each FOUP through a sealable access door 521. The substrate handling device 512 moves linearly along a track 523 to facilitate access to all of the modules and tools.

The atmospheric transfer chamber 510 is coupled to the pair of load locks 506 and 508 through sealable doors 505 and 509 such that the substrate handling device 512 can access the load locks 506 and 508. The sub-atmospheric platform 504 comprises a central sub-atmospheric transfer chamber 530 and a plurality of process chambers 556, 558, 560, and 562. Sealable doors 507 and 511 respectively couple each load lock 506 and 508 to the sub-atmospheric transfer chamber 530. The sub-atmospheric transfer chamber 530 contains a substrate handing device 532, such as a robot, that accesses the load locks 506 and 508 as well as the process chambers 556, 558, 560 and 562. The process chambers 556, 558, 560 and 562 are each coupled to the sub-atmospheric transfer chamber 530 via separately closable and sealable openings, such as slit-valves. The process chambers 556, 558, 560 and 562 may comprise one or more etching chambers such as the DPS chamber depicted in FIG. 1. Additionally, one or more photoresist stripping chambers such as the ASP chamber described above may be used as one or more of the process chambers 556, 558, 560 and 562. As described above, the ASP chamber, if used, may be located either on the sub-atmospheric platform 504 or the atmospheric platform 502. FIG. 5 shows the sub-atmospheric platform 504 comprising two etch chambers 558 and 560 and two photoresist stripping chambers 556 and 562. The sub-atmospheric platform 504 is, for example, a CENTURA platform available for Applied Materials, Inc. of Santa Clara, Calif.

The platform 500 also includes a system computer 570 that is coupled to and controls each module that is coupled to the atmospheric and sub-atmospheric platforms 502 and 504, controls the substrate handling devices 512 and 532, and controls the load locks 506 and 508. Generally, the system computer 570 controls all aspects of operation of the platform 500 either by direct control of the sub-systems, modules, tools and apparatus or by controlling the computers associated with those sub-systems, modules, tools and apparatus. The system computer 570 enables feedback from one module or tool to be used to control the flow of substrates through the platform 500 and/or control the processes or operation of the various modules and tools to optimize substrate throughput.

While the foregoing is directed to embodiments of the present invention, other and further embodiments of the invention may be devised without departing from the basic scope thereof, and the scope thereof is determined by the claims that follow.

1. A method of etching a film stack, wherein the film stack comprises at least one layer of magnetic material, the method comprising:
forming a high temperature mask on the film stack;
etching the film stack, wherein etching produces a residue comprising components of the high temperature mask; and
removing the high temperature mask and the residue.

2. The method of claim 1 wherein the high temperature mask comprises inorganic carbon.

3. The method of claim 2 wherein the inorganic carbon is amorphous carbon.

4. The method of claim 2 wherein the high temperature mask further comprises nitrogen.

5. The method of claim 1 wherein the high temperature mask has a thickness in a range of about 200 Angstroms to about 5000 Angstroms.

6. The method of claim 1 further comprising depositing a cap layer on the high temperature mask.

7. The method of claim 6 wherein the cap layer comprises a material selected from the group consisting of a nitride, an oxide, an oxynitride, and combinations thereof.

8. The method of claim 6 wherein the cap layer has a thickness in a range of about 100 Angstroms to about 500 Angstroms.

9. The method of claim 1 wherein the residue comprises carbon and a metallic component.

10. The method of claim 9 wherein the metallic component comprises a material selected from the group consisting of tantalum, titanium, cobalt, nickel, iron, ruthenium, platinum, and combinations thereof.

11. The method of claim 1 wherein the film stack is etched using a plasma.

12. The method of claim 1 wherein the film stack is etched at a temperature of about 250 degrees Celsius or greater.

13. The method of claim 1 wherein the residue is removed from a sidewall of a material layer selected from the group consisting of one or more magnetic layers, a tunneling layer formed between the magnetic layers, and combinations thereof.

14. A method of etching a film stack, wherein the film stack comprises at least one layer of magnetic material, the method comprising:
forming a high temperature mask layer on the film stack;
using the high temperature mask to etch a conductive layer and at least one magnetic layer within the film stack; and
removing the high temperature mask and a residue comprising components of the high temperature mask.

15. The method of claim 14 wherein the high temperature mask comprises inorganic carbon.

16. The method of claim 15 wherein the inorganic carbon is amorphous carbon.

17. The method of claim 15 wherein the high temperature mask further comprises nitrogen.

18. The method of claim 14 wherein the high temperature mask has a thickness in a range of about 200 Angstroms to about 5000 Angstroms.

19. The method of claim 14 further comprising depositing a cap layer on the high temperature mask.

20. The method of claim 19 wherein the cap layer comprises a material selected from the group consisting of a nitride, an oxide, an oxynitride, and combinations thereof.

21. The method of claim 19 wherein the cap layer has a thickness in a range of about 100 Angstroms to about 500 Angstroms.

22. The method of claim 14 wherein the residue comprises carbon and a metallic component.

23. The method of claim 22 wherein the metallic component comprises a material selected from the group consisting of tantalum, titanium, cobalt, nickel, iron, ruthenium, platinum, and combinations thereof.

24. The method of claim 14 wherein the film stack is etched using a plasma.

25. The method of claim 14 wherein the film stack is etched at a temperature of about 250 degrees Celsius or greater.

26. The method of claim 14 wherein the residue is removed from a sidewall of a material layer selected from the group consisting of one or more magnetic layers, a tunneling layer formed between the magnetic layers, and combinations thereof.

27. A method of etching a film stack, wherein the film stack comprises at least one layer of magnetic material, the method comprising:
forming a mask comprising inorganic carbon on the film stack;
using the mask to etch a conductive layer and the at least one layer of magnetic material at a temperature of about 250 degrees Celsius or greater; and
removing the mask and a residue, wherein the residue comprises carbon from the mask and metallic components from the film stack.

28. The method of claim 27 wherein the inorganic carbon is amorphous carbon.

29. The method of claim 27 wherein the mask further comprises nitrogen.

30. The method of claim 27 wherein the mask has a thickness in a range of about 200 Angstroms to about 5000 Angstroms.

31. The method of claim 27 further comprising depositing a cap layer on the mask.

32. The method of claim 31 wherein the cap layer comprises a material selected from the group consisting of a nitride, an oxide, an oxynitride, and combinations thereof.

33. The method of claim 31 wherein the cap layer has a thickness in a range of about 100 Angstroms to about 500 Angstroms.

34. The method of claim 27 wherein the metallic components comprise a material selected from the group consisting of tantalum, titanium, cobalt, nickel, iron, ruthenium, platinum, and combinations thereof.

35. The method of claim 27 wherein the film stack is etched using a plasma.

36. The method of claim 27 wherein the residue is removed from a sidewall of a material layer selected from the group consisting of one or more magnetic layers, a tunneling layer formed between the magnetic layers, and combinations thereof.

37. A computer readable medium containing a software routine that, when executed causes a general purpose computer to control a process chamber using a method, comprising:
forming a high temperature mask on the film stack;
etching the film stack, wherein etching produces a residue comprising components of the high temperature mask; and
removing the high temperature mask and the residue.
